(19) United States
(12) Patent Application Publication
(10) Pub. No.: US 2026/0026302 A1
(43) Pub. Date: Jan. 22, 2026

(54) COMBINED LONG-STROKE AND SHORT-STROKE POSITIONING STAGE

(71) Applicant: ASMPT Singapore Pte. Ltd., Singapore (SG)

(72) Inventors: Kuok Hang MAK, Hong Kong (CN); Ka Shing KWAN, Singapore (SG); Wai Kwong MOK, Hong Kong (CN)

(21) Appl. No.: 18/774,205

(22) Filed: Jul. 16, 2024

(51) Int. Cl. H01L 21/68; H01L 21/687

(52) U.S. Cl. CPC H10P 72/50; H10P 72/7618

(57) ABSTRACT

A planar positioning stage has an integrated planar motion stage that is drivable to move to different locations on a plane, and a planar fixture stage contained within the integrated planar motion stage. Multiple coil assemblies are mounted on the integrated planar motion stage that are configured for electromagnetic interaction with magnets mounted on the planar fixture stage. The said electromagnetic interaction may selectively either couple the planar fixture stage to move together with the integrated planar motion stage or to decouple the planar fixture stage from the integrated planar motion stage to drive the planar fixture stage to move relative to the integrated planar motion stage.

### FIELD OF THE INVENTION

The invention relates to semiconductor assembly and packaging equipment, and in particular to a positioning mechanism for precisely positioning a stage along a plane during operations conducted on an object that is being held on the stage.

### BACKGROUND AND PRIOR ART

In the semiconductor assembly and packaging industry, conventional planar positioning stages for equipment such as die bonders and wire bonders that bond semiconductor dies or conductive wires onto substrates, are typically constructed in a stacked configuration. Included in such a stack is a linear stage that is movable along a first axis, and this linear stage is mounted and stacked onto another linear stage that is movable along a second axis perpendicular to the first axis. An example of such a stacked planar positioning stage is described in U.S. Patent Number 6,983,703 B2 entitled “Driving Means to Position a Load”.

In such a stacked stage configuration, the motion performances of the two linear axes would tend to be different as they have different inherent payloads and dynamic properties. In particular, it is challenging for stacked stages to achieve sub-micron position accuracy when they are being driven with high acceleration.

More recently, planar movable stages that avoid the aforesaid stacked configuration have been gaining popularity in the market although they are still less common. They are capable of offering better motion performance than stacked movable stages, especially for achieving better contour motion performance.

One of the most important factors that determines the motion performance of a positioning stage pertains to the natural frequencies of its movable stage. The fundamental natural frequency of these plate-like planar stages is relatively low due to the fact that the bending stiffness of a plate structure is typically also low. As such, these plate-like planar stages cannot operate at high accelerations. Otherwise, their motion accuracies are reduced. Moreover, unless it is adequately isolated, a reaction force from the planar motor will be transferred to its base and then eventually to the machine. If high motion precision must be achieved, then the planar stage cannot run at high accelerations in order to minimize the motor force to ensure that vibration is not excited by the reaction force from the planar motor onto the machine. If machine vibration is generated by the motor reaction force, the motion precision of the planar stage would also be affected by the vibration of the machine.

Furthermore, a travel range of a planar stage is determined by the area of the plane that the planar motor is meant to cover. Typically, a stator of the planar motor comprises a set of coil assemblies. If the planar stage requires a greater travel range, more coil assemblies would have to be added to the stator of the planar motor accordingly. As a result, it is likely that there would be greater heat generated from the coil assemblies, and a more sophisticated cooling system is required to prevent the planar motor from overheating.

For the aforesaid reasons, these plate-like planar stages may not be suitable for operating at high levels of acceleration and large travel ranges required in the semiconductor assembly and packaging industry, especially when high precision is also required in their motion trajectories. It would thus be beneficial to develop a planar stage that avoids the aforesaid shortcomings of the prior art.

### SUMMARY OF THE INVENTION

It is thus an object of the invention to seek to provide a planar positioning stage that is capable of operating at high levels of acceleration with less vibration over a relatively large travel range to achieve more precise positioning than prior art positioning stages.

According to a first aspect of the invention, there is provided a planar positioning stage comprising: an integrated planar motion stage that is drivable to move to different locations on a plane; a planar fixture stage contained within the integrated planar motion stage; and multiple coil assemblies mounted on the integrated planar motion stage that are configured for electromagnetic interaction with magnets mounted on the planar fixture stage; wherein the said electromagnetic interaction is operative to selectively couple the planar fixture stage to move together with the integrated planar motion stage, and decouple the planar fixture stage from the integrated planar motion stage to drive the planar fixture stage to move relative to the integrated planar motion stage.

According to a second aspect of the invention, there is provided a method of positioning a planar fixture stage of a planar positioning stage including the planar fixture stage and an integrated planar motion stage to a target position, comprising the steps of: driving the integrated planar motion stage to move to different locations on a plane while selectively coupling the planar fixture stage contained within the integrated planar motion stage to move together with the integrated planar motion stage by electromagnetic interaction between multiple coil assemblies mounted on the integrated planar motion stage with magnets mounted on the planar fixture stage; selectively decoupling the planar fixture stage from the integrated planar motion stage; and driving the planar fixture stage to move relative to the integrated planar motion stage to the target position via the said electromagnetic interaction between the multiple coil assemblies and the magnets.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

A specific example of a positioning stage in accordance with the invention will now be described with reference to the accompanying drawings, in which:

FIG. 1 is an isometric view of a planar positioning stage according to the preferred embodiment of the invention;

FIG. 2 is a plan view of the planar positioning stage shown in FIG. 1;

FIG. 3 is a cross-sectional view of the planar positioning stage as seen along line A-A in FIG. 2;

FIG. 4 is an enlarged cross-sectional view of a motor assembly for driving a planar stage of the planar positioning stage;

FIG. 5 is an isometric view of a bottom surface of the planar stage; and

FIG. 6 is a plan view of the planar positioning stage wherein the planar stage has been located at a position that is spaced from its standby position as illustrated in FIG. 2.

### DETAILED DESCRIPTION OF THE PREFERRED EMBODIMENTS OF THE INVENTION

FIG. 1 is an isometric view of a planar positioning stage 10 according to the preferred embodiment of the invention. The planar positioning stage 10 generally includes a base 12 onto which various driving mechanisms are assembled.

A long-stroke motion stage, which may be in the form of an integrated planar motion stage 14, as well as a short-stroke motion stage, which may be in the form of a planar fixture stage 16, are mounted onto the base 12. The integrated planar motion stage 14 is drivable to move to different locations on a plane parallel to a top surface of the base 12, and is generally configured to drive a work-holder (not shown) on a planar stage 30 comprised in the planar fixture stage 16 for longer distances but with lower accuracy. The planar fixture stage 16 is located more centrally on the base 12 and is contained within the integrated planar motion stage 14. The integrated planar motion stage 14 is designed to carry the work-holder incorporated on the planar fixture stage 16 across the base 12 to cover an entire working area, whereas the planar fixture stage 16 is designed to offer higher acceleration and higher position accuracy and repeatability for positioning the work-holder within a local region of the working area after the planar fixture stage 16 has been positioned by the integrated planar motion stage 14 on the base 12.

Both the X and Y linear axes in the integrated planar motion stage 14 are constructed such that the centers of mass of the two axes are coincident, and these centers of mass are also coincident with the center of mass of the planar fixture stage 16 along the X and Y linear axes travelled by the respective integrated planar motion stage 14 and planar fixture stage 16 on the base 12. Such a design can effectively reduce any offset of their centers of gravity, as the lines of action of the motion forces would be acting on the centers of mass in order to avoid any moments from being produced by the motor forces. Moreover, since the planar stage 30 is not physically mounted onto the integrated planar motion stage 14, any mechanical noise or disturbance from the operations the integrated planar motion stage 14 do not adversely affect the performance of the planar stage 30.

The integrated planar motion stage 14 comprises a first movable carriage, such as a Y carriage 18, which is drivable to move along a first axis (such as the Y axis) by means of Y linear motors 20 along Y guide rails 22. Instead of linear motion guide rails, other guideways such as air bearings or air bushings may be used. A second movable carriage, such as an X carriage 24, is installed and contained within a perimeter of the Y carriage 18. The X carriage 24 is mounted onto the Y carriage 18, and is operatively connected to the Y carriage 18 via X linear motors 26, and is drivable to move by means of the X linear motors 26 along a second axis orthogonal to the first axis (such as the X axis) along X guide rails 23 mounted onto the Y carriage 18. The X carriage 24 is enclosed by the Y carriage 18 so as to make their centers of mass coincident and to attain as much symmetry as possible.

The planar stage 30 is further located and contained within a perimeter of the X carriage 24, and the planar stage 30 is operatively connected to the X carriage 24 via a planar motor 28, which may be in the form of multiple double-sided iron core motors. The planar motor 28 is operative to drive the planar stage 30 to move along X, Y and rotary (Rz) directions on the X-Y plane.

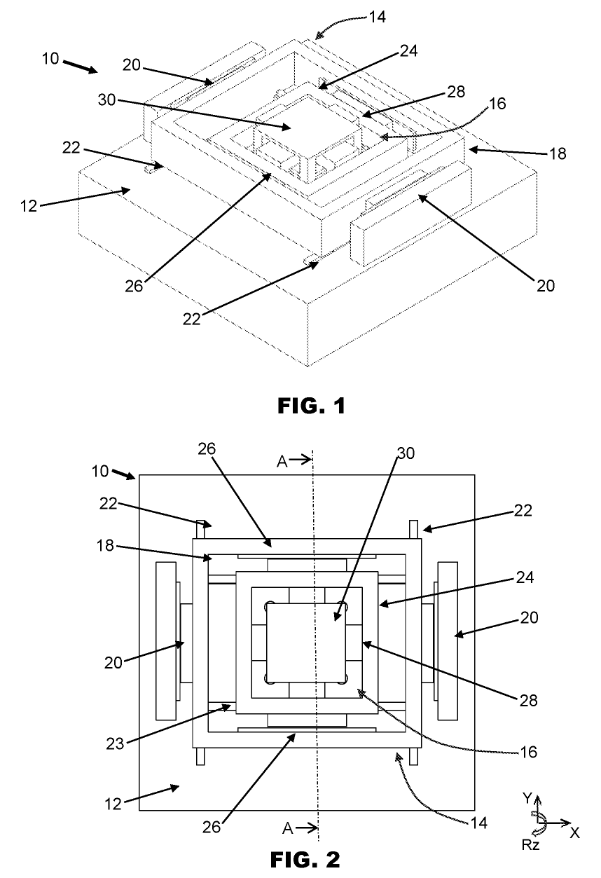

FIG. 2 is a plan view of the planar positioning stage 10 shown in FIG. 1. The plan view shows that the Y carriage 18 of the integrated planar motion stage 14 is drivable by the Y linear motors 20 to move on the base 12 in the Y direction while being guided by the Y guide rails 22. The Y linear motors 20 may, for instance, comprise a movable coil attached to the Y carriage 18 that is translatable relative to a stationary magnet installed on the base 12, or alternatively a movable magnet attached to the Y carriage 18 that is translatable relative to a stationary coil installed on the base 12.

In turn, the X carriage 24 of the integrated planar motion stage 14 is drivable by the X linear motors 26 to move on the Y carriage 18 in the X direction while being guided by the X guide rails 23. Similarly, the X linear motors 26 may comprise a movable coil attached to the X carriage 24 that is translatable relative to a stationary magnet installed on the Y carriage 18, or alternatively a movable magnet attached to the X carriage 24 that is translatable relative to a stationary coil installed on the Y carriage 18.

The combination of movements of the Y carriage 18 and X carriage 24 comprised in the integrated planar motion stage 14 allow the planar stage 30 that is enclosed within a perimeter of the X carriage 24 to be positioned at various positions on the base 12 over longer distances while the planar stage 30 is coupled or locked to the X carriage 24 by electromagnetic interaction. However, the accuracy of such positioning need not be very high over longer distances as long as the planar stage 30 can be speedily locatable at an approximate position for fine positioning to be subsequently carried out more precisely by the planar fixture stage 16.

The planar fixture stage 16 comprises the planar stage 30 which is drivable by the planar motor 28 within the confines of the X carriage 24 for fine positioning once the planar stage 30 has been positioned by the Y carriage 18 and X carriage 24 to an approximate location whereat the work-holder which is carried by the planar stage 30 is required.

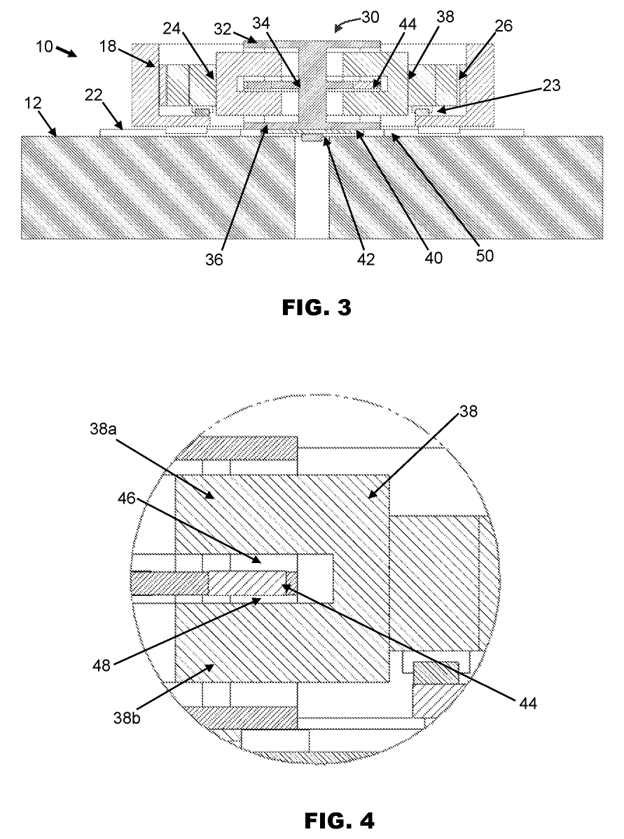

FIG. 3 is a cross-sectional view of the planar positioning stage 10 as seen along line A-A in FIG. 2. The Y carriage 18 is guided by the Y guide rails 22 to move in the Y axis on a top surface of the base 12. The X carriage 24 is guided by the X rails 23 installed on the Y carriage 18 to move in the X axis while being driven by the X linear motors 26.

The planar motor 28 comprises a motor coil assembly 38 that is mounted onto the X carriage 24, and a motor magnet assembly 44 that is embedded in the planar stage 30 to form multiple double-sided iron core motors. Hence, the motor magnet assembly 44 may comprise an iron core magnet. It can be seen in FIG. 3 that the planar stage 30 is constructed in the form of a three-layer tower, including a top layer 32, middle layer 34 and bottom layer 36. The magnets comprised in the motor magnet assembly 44 are preferably embedded in the middle layer 34 of the planar stage 30, so that the motor magnet assembly 44 may be insertable into a gap in the motor coil assembly 38 that is formed by coils on top and bottom sides of the motor coil assembly 38. Hence, the iron core magnet of the motor magnet assembly 44 is movable parallel to opposite top and bottom sides of the motor coil assembly 38 via electromagnetic interaction. With such a design, the planar stage 30 is movable within an area bounded by the motor coil assemblies 38.

The top layer 32 of the planar stage 30 may be a work-table on which a work piece is mounted or held for processing. As mentioned, a mover of the planar motor 28 in the form of the motor magnet assembly 44 is mounted onto the middle layer 34. A position encoder as well as air bearing pads 50 are attached to the bottom layer 36 to control movement of the planar stage 30.

The air bearing pads 50 attached to the bottom layer 36 of the planar stage 30 allow the planar stage 30 to slide along the top surface of the base 12 without friction by being air-floated. The base 12 is typically made of granite, which offers exceptional flatness and surface finish, so that the planar stage 30 is able to travel in a frictionless manner to achieve the highest possible motion accuracy and repeatability. Unlike conventional mechanical guideways, air bearings effected by the air bearing pads 50 do not involve any moving parts that may cause mechanical wear.

The bottom layer 36 also includes an encoder scale 40, whilst the base 12 correspondingly includes an encoder scanning head 42 which is fixedly mounted onto the base 12. The encoder scale 40 and encoder scanning head 42 together comprise a two-dimensional encoding system, so that displacements of the planar stage 30 in the X and Y linear and rotary (Rz) directions may be measured in real time through readings obtained from the relative motion between the encoder scanning head 42 and the encoder scale 40. It would be appreciated that, alternatively, the encoder scale 40 may be located on the base 12 while the encoder scanning head 42 may be fixedly mounted onto the bottom layer 36.

FIG. 4 is an enlarged cross-sectional view of the planar motor 28 for driving the planar stage 30 of the planar positioning stage 10. The motor magnet assembly 44 incorporated in the middle layer 34 of the planar stage 30 is inserted into a gap within the generally U-shaped motor coil assembly 38. This leaves an upper motor air gap 46 between an upper motor stator 38a and the motor magnet assembly 44, and a lower motor air gap 48 between a lower motor stator 38b and the motor magnet assembly 44, and allows electromagnetic interaction between the motor coil assembly 38 and the motor magnet assembly 44 to drive the planar stage 30 to move with high precision on the X-Y plane. In order to drive the planar stage 30 in all directions along the X-Y axis, there are four motor coil assemblies 38 mounted at all four sides of the planar stage 30. The four sides of the middle layer 34 of the planar stage 30 are therefore inserted into air gaps of the four motor coil assemblies 38.

When a current is passed through each motor coil assembly 38, a resultant force is generated from electromagnetic interaction between the motor coil assembly 38 and the corresponding motor magnet assembly 44 inserted into the gap in the motor coil assembly 38. The four motor assemblies 38 primarily serve to generate resultant forces in the X and Y directions along which each motor coil assembly 38 is aligned.

The said electromagnetic interaction is operative to selectively couple the planar fixture stage 16 to move together with the integrated planar motion stage 14 for positioning over longer distances, and also to selectively decouple the planar fixture stage 16 from the integrated planar motion stage 14 to drive the planar fixture stage 16 to move relative to the integrated planar motion stage 14 during fine positioning.

In operation, the motor magnet assembly 44 embedded in the middle layer 34 of the planar stage 30 is attracted by both the upper and lower motor stators 38a, 38b comprised in the motor coil assembly 38. To ensure an adequate stiffness of the air bearings generated by the air bearing pads 50, it is necessary for a predetermined level of preloading to be exerted on the planar stage 30 as designated by the air bearing manufacturer. In this case, the air bearings are preloaded by magnetic attractions that exist intrinsically between the upper and lower motor stators 38a, 38b of the motor coil assembly 38 and a mover (i.e., the motor magnet assembly 44) of the planar motor 28.

In order to obtain a resultant force acting downward to preload the air bearings generated by the air bearing pad 50, the upper motor air gap 46 is designed to be greater than the lower motor air gap 48. Therefore, the planar motor 28 is not only used to actuate the planar stage 30, but it is also used to preload the air bearings. Using such a mechanical arrangement, no additional magnets are required to be mounted on the planar motor 28 to further generate a preload on the air bearings. Similarly, the three-layer tower may be selectively coupled by electromagnetic interactions between the upper and lower motor stators 38a, 38b and the magnet assemblies 44 to lock the planar stage 30 to the X carriage 24 to move together with the X carriage 24.

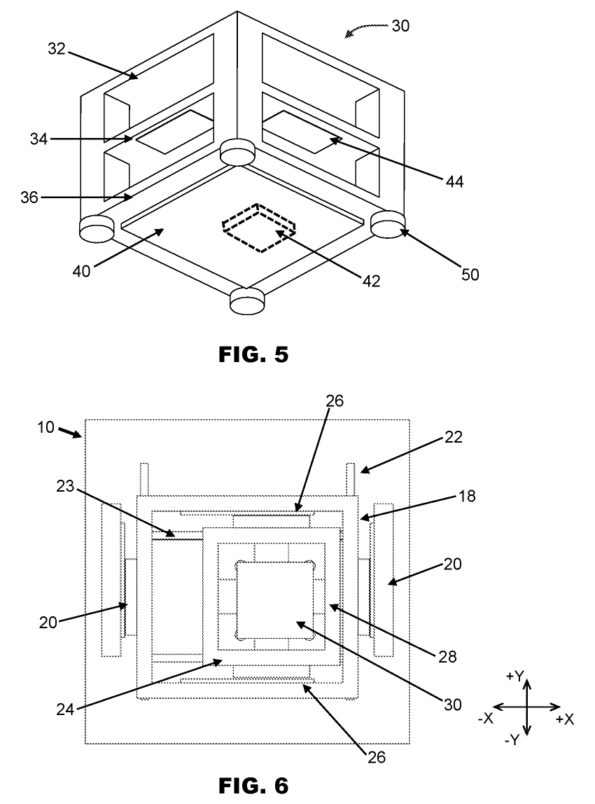

FIG. 5 is an isometric view of a bottom surface of the planar stage 30. The top layer 32, middle layer 34 and bottom layer 36 are Illustrated. Also illustrated are the four motor magnet assemblies 44 incorporated adjacent to each of the four sides of the middle layer 34 of the planar stage 30. These motor magnet assemblies 44 are inserted into gaps in each of the four motor coil assemblies 38 to form the planar motor 28.

It would be noted that the planar stage 30 is designed to have a high structural stiffness to offer excellent dynamical properties which are essential for the planar stage 30 to operate at high acceleration while still achieving microscale motion accuracy. There is a high level of symmetry in its three-layer tower structure and its material is distributed to increase its stiffness. Such a tower structure has a much higher bending stiffness as compared to a simple plate or planar structure.

The planar motor 28 includes four powerful double-sided iron core motors which are located around the planar stage 30 at predetermined angles. Two of the four double-sided iron core motors forming the planar motor 28 are aligned in the X direction and the other two double-sided iron core motors are aligned in the Y direction, allowing the planar stage 30 to move in the X, Y as well as rotary directions. Also, a cooling system (not shown) may be integrated into the planar motor 28 to lower the motor temperature and prevent over-heating.

For accurate real-time positioning of the planar stage, the encoder scale 40 is mounted onto a lower surface of the bottom layer 36, and the encoder scale 40 is readable by the encoder scanning head 42. The encoder scanning head 42 is represented in dotted lines as it is fixedly mounted onto the base 12 while the planar stage 30 carrying the encoder scale 40 is movable relative to the base 12 and the encoder scanning head 42.

FIG. 6 is a plan view of the planar positioning stage 10 wherein the planar stage 10 has been located at a position that is spaced from its standby position as illustrated in FIG. 2. In FIG. 6, the Y carriage 18 has been moved in the -Y direction by the Y linear motors 20 along the Y guide rails 22. At the same time, the X carriage 24 has been moved in the +X direction by the X linear motors 26 along the X guide rails 23.

During an indexing process associated with the aforesaid positioning of the Y and X carriages 18, 24, the integrated planar motion stage 14 carries the planar fixture stage 16 to travel with it in a synchronous manner. Even though the integrated planar motion stage 14 carries the planar fixture stage 16, there is no rigid mechanical connection between the integrated planar motion stage 14 and the planar stage 30 incorporating the work-holder. Hence, during such indexing process, the planar motor 28 provides an electromagnetic force to lock the X, Y and rotary positions of the planar fixture stage 16 with respect to the integrated planar motion stage 14. In this particular mechanical configuration that is presented in the preferred embodiment of the invention, the planar stage 30 is physically separate from and is completely physically decoupled from the integrated planar motion stage 14 in certain linear and rotary directions (specifically in the Z, pitch and roll directions), so that any dynamic disturbances in these directions do not affect the planar stage 30 of the planar fixture stage 16, which is designed to achieve the finest and most accurate position.

Following the aforesaid indexing, the planar stage 30 is driven by the planar motor 28 in the +X and -Y directions through electromagnetic interaction between the four motor coil assemblies 38 and motor magnet assemblies 44, so that the planar stage 30 appears to be nearer to two sides of the X carriage 24, as compared with the other two opposite sides of the X carriage 24. If necessary, the planar stage 30 may also be rotated about the Z axis relative to the X carriage 24. Hence, an end-effector of the semiconductor assembly and packaging machine is able to work on a component held on the work-holder on the top layer 32 of the planar stage 30 with high positioning accuracy. In contrast to purely stacked stages, it is possible for such a planar stage 30 to achieve not just sub-microscale accuracy, but also nanoscale accuracy.

It should be appreciated that the planar positioning stage 10 as described in the preferred embodiment of the invention offers outstanding planar motion performance while being minimally affected by vibrations when operating at high levels of acceleration. Decoupling of the planar fixture stage 16 from the integrated planar motion stage 14 plays a key role in allowing the planar fixture stage 16 to achieve very accurate positions without being affected by dynamic disturbance transmitted from the integrated planar motion stage 14.

One of the most important features of the configuration of the planar positioning stage 10 is that vibrations of the mechanical system will have very low transmissibility to a machine or a platform that it is mounted onto. With such a mechanical configuration in combination with the mode of operation as described herein, the vibration transmissibility from the planar positioning stage 10 to the machine platform is made very low. Since the machine itself is isolated vibrationally from the planar positioning stage 10, the machine is unlikely to be excited by the planar positioning stage 10 and is able to maintain a steady and mechanically noise-free platform not only for the planar positioning stage 10, but also for all other mechanical, electrical and optical modules, etc. mounted on the machine.

With the aid of the integrated planar motion stage 14, the planar stage 30 may be moved to any position within an entire work area to offer its excellent motion performance without having to extend a travel range of only the planar stage 30 by itself. It is therefore worth mentioning that extending the travel range of the planar stage 30 is likely to deteriorate the motion performance and reduce the maximum acceleration that is possible for the planar stage 30. This limitation has been avoided by the present invention.

Moreover, the planar positioning stage 10 is configured to operate in such a way that a reaction force generated from the planar motor 28 is transferred to the integrated planar motion stage 14, which then gains momentum to travel in the X and Y directions. Therefore, the machine or platform does not experience the force from the planar motor 28. In other words, motor forces from the planar motor 28 do not turn into a source of vibration for the machine.

To drive the planar stage 30 continuously at high accelerations, the planar motor 28 may generate immense heat, and an air-cooling system may be integrated into the planar motor 28 to keep the temperature of the motor coils below a predetermined temperature (typically 90°C) to prevent the planar motor 28 from overheating. In such an air-cooling system, air may be supplied to flow through a series of heatsink fins and air channels to absorb the heat generated by the coils of the planar motor, as is known by persons skilled in the art. Thus, it would be appreciated that a simplified cooling system may be incorporated to maintain an optimal operating temperature of the planar positioning stage 10.

The invention described herein is susceptible to variations, modifications and/or additions other than those specifically described and it is to be understood that the invention includes all such variations, modifications and/or additions which fall within the spirit and scope of the above description.

1. A planar positioning stage comprising:
an integrated planar motion stage that is drivable to move to different locations on a plane;
a planar fixture stage contained within the integrated planar motion stage; and
multiple coil assemblies mounted on the integrated planar motion stage that are configured for electromagnetic interaction with magnets mounted on the planar fixture stage;
wherein the said electromagnetic interaction is operative to selectively couple the planar fixture stage to move together with the integrated planar motion stage, and decouple the planar fixture stage from the integrated planar motion stage to drive the planar fixture stage to move relative to the integrated planar motion stage.

2. The planar positioning stage as claimed in claim 1, wherein the integrated planar motion stage further comprises a first carriage movable along a first linear axis and a second carriage mounted on the first carriage that is movable along a second linear axis orthogonal to the first linear axis.

3. The planar positioning stage as claimed in claim 2, wherein the second carriage is enclosed by the first carriage and the center of mass of the first carriage is coincident with the center of mass of the second carriage.

4. The planar positioning stage as claimed in claim 3, wherein the multiple coil assemblies are mounted on the second carriage and the planar fixture stage is contained within the second carriage and is movable within an area bounded by the multiple coil assemblies.

5. The planar positioning stage as claimed in claim 1, wherein the planar fixture stage is in the form of a three-layer tower having a top layer, a middle layer and a bottom layer.

6. The planar positioning stage as claimed in claim 5, wherein the magnets are embedded in the middle layer to form magnet assemblies, and the coil assemblies each further comprises an upper stator and a lower stator including a gap therebetween such that each magnet assembly is insertable into the gap between the upper stator and the lower stator.

7. The planar positioning stage as claimed in claim 6, wherein the bottom layer includes either one of an encoder scale or an encoder scanning head, and the plane comprises a top surface of a base which includes the other one of the encoder scale or encoder scanning head.

8. The planar positioning stage as claimed in claim 7, wherein the combination of encoder scale and encoder scanning head forms a two-dimensional encoding system for measuring linear and rotary displacements of the planar fixture stage.

9. The planar positioning stage as claimed in claim 6, further comprising an upper motor air gap between each upper stator and each magnet assembly and a lower motor air gap between each lower stator and each magnet assembly when each magnet assembly is inserted into each coil assembly.

10. The planar positioning stage as claimed in claim 6, wherein the middle layer comprises four magnet assemblies embedded at four sides of the middle layer that are insertable into the gaps in four corresponding coil assemblies.

11. The planar positioning stage as claimed in claim 6, wherein the three-layer tower is selectively coupled by magnetic attraction between the upper stators and lower stators and the magnet assemblies to lock the planar fixture stage to move together with the integrated planar motion stage.

12. The planar positioning stage as claimed in claim 6, wherein the top layer includes a work-table, and the bottom layer includes air bearing pads to enable the planar fixture stage to slidably move along the plane.

13. The planar positioning stage as claimed in claim 12, wherein magnetic attraction between the coil assemblies and magnets is operative to exert a preload force onto the air bearing pads.

14. The planar positioning stage as claimed in claim 1, wherein the multiple coil assemblies and magnets form multiple double-sided iron core motors for driving the planar fixture stage to move in both linear and rotary directions.

15. The planar positioning stage as claimed in claim 1, wherein the integrated planar motion stage is configured to drive a work-holder fixed on the planar fixture stage for relatively longer distances than the planar fixture stage, but with relatively lower accuracy than the planar fixture stage.

16. The planar positioning stage as claimed in claim 1, wherein the planar fixture stage is configured to drive a work-holder fixed on the planar fixture stage with relatively higher acceleration and repeatability then the integrated planar motion stage.

17. The planar positioning stage as claimed in claim 1, wherein the planar fixture stage is located centrally within the integrated planar motion stage.

18. The planar positioning stage as claimed in claim 1, wherein the planar fixture stage is physically separate and decoupled from the integrated planar motion stage.

19. The planar positioning stage as claimed in claim 1, wherein the integrated planar motion stage and the planar fixture stage are constructed such that a center of mass of the integrated planar motion stage is coincident with a center of mass of the planar fixture stage along orthogonal linear axes travelled by the respective stages on the plane.

20. A method of positioning a planar fixture stage of a planar positioning stage including the planar fixture stage and an integrated planar motion stage to a target position, comprising the steps of:
driving the integrated planar motion stage to move to different locations on a plane while selectively coupling the planar fixture stage contained within the integrated planar motion stage to move together with the integrated planar motion stage by electromagnetic interaction between multiple coil assemblies mounted on the integrated planar motion stage with magnets mounted on the planar fixture stage;
selectively decoupling the planar fixture stage from the integrated planar motion stage; and
driving the planar fixture stage to move relative to the integrated planar motion stage to the target position via the said electromagnetic interaction between the multiple coil assemblies and the magnets.
